(19) United States
(12) Patent Application Publication
(10) Pub. No.: US 2010/0053916 A1
(43) Pub. Date: Mar. 4, 2010

(54) CARD HOLDING MECHANISM

(75) Inventors: YAN-MEI ZHANG, Shenzhen City (CN); HSIAO-HUA TU, Shindian (TW); JUN WANG, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/510,799

(22) Filed: Jul. 28, 2009

(30) Foreign Application Priority Data
Aug. 27, 2008 (CN) 200810304223.1

(51) Int. Cl. H05K 5/00

(52) U.S. Cl. 361/754

(57) ABSTRACT

The invention discloses a card holding mechanism, which includes a housing, a retaining member mounting in one side of the housing and a sliding button slidably attached on another side of the housing. The housing defines a chamber therein, and the chamber is used for accommodating a chip card. The bottom of the chamber defines a through hole. The retaining member is used for receiving the chip card. The sliding button is fixed with the retaining button through the through hole. The chip card is accommodated in the chamber and is secured by the retaining member, when the sliding button is pushed, then the chip card with the retaining member are brought out from the chamber.

### BACKGROUND

1. Technical Field

The disclosure relates to card holding mechanisms used in portable electronic devices, and particularly, to a card holding mechanism for holding a chip card.

2. Description of Related Art

Commonly, portable electronic devices, such as mobile phones, use chip cards retained by a holder.

Typically, chip card holders define a receiving groove for receiving the chip card, such as a subscriber identity module (SIM) card. The chip card is partly received in the receiving groove to electronically connect to a circuit of the device employing the chip card, and partly exposed so that it may be gripped for removal. However, the exposed part of the chip card is usually small and therefore difficult for a user to grasp in removing the chip card from the holder.

Therefore, there is a room for improvement within the art.

### BRIEF DESCRIPTION OF THE DRAWINGS

Many aspects of a card holding mechanism can be better understood with reference to the following drawings. The components in the drawings are not necessarily to scale, the emphasis instead being placed upon clearly illustrating the principles of the present card holding mechanism. Moreover, in the drawings, like reference numerals designate corresponding parts throughout the several views.

FIG. 1 is a schematic and partial exploded view of a card holding mechanism with a chip card according to an exemplary embodiment.

FIG. 2 is similar to FIG. 1 but shown from another angle.

FIG. 3 is a schematic assembled view of the card holding mechanism shown in FIG. 1 with the chip card partially installed.

FIG. 4 is a schematic assembly view of the card holding mechanism shown in FIG. 1 with the chip card installed.

FIG. 5 is an assembled cross-sectional view taken along line V-V of FIG. 3, showing the chip card in partially installed.

FIG. 6 is an assembled cross-sectional view taken along line VI-VI of FIG. 4, showing the chip card installed.

### DETAILED DESCRIPTION OF THE EMBODIMENTS

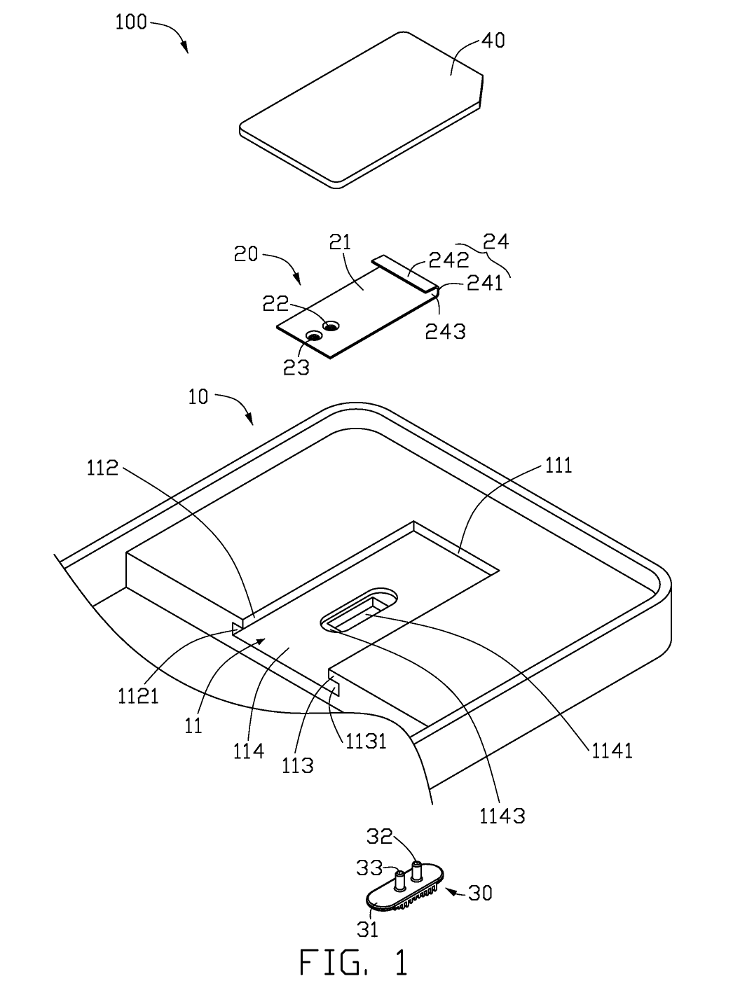

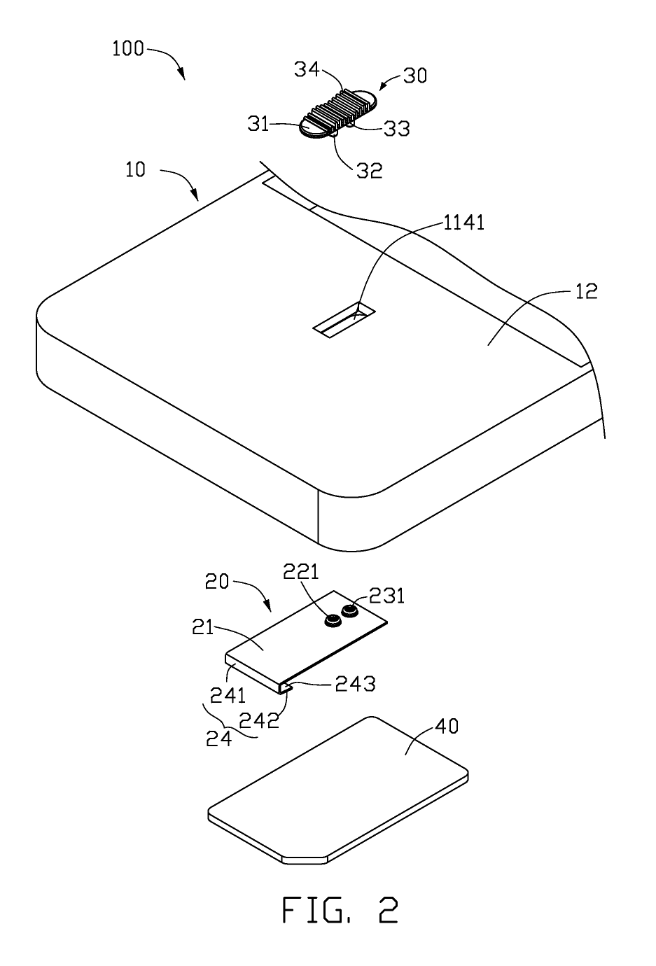

Referring to the drawings, FIGS. 1-2 show an exemplary card holding mechanism 100 applied in a portable electronic device (not shown), such as a mobile phone. The card holding mechanism 100 includes a housing 10, a retaining member 20 configured to be received in the housing 10, and a sliding button 30 slidable on the housing 10. A chip card 40 (e.g., SIM card) is secured in the housing 10 by the retaining member 20.

The housing 10 includes a chamber 11 and a surface 12 defined opposite the chamber 11. The chamber 11 is positioned at one end of the housing 10 for accommodating the retaining member 20 and the chip card 40. The chamber 11 includes a stopping wall 111, two sidewalls 112, 113 extending perpendicularly from two ends of the stopping wall 111, and a bottom surface 114 perpendicularly connected to the stopping wall 111 and two sidewalls 112, 113. The sidewalls 112, 113 define guiding grooves 1121 and 1131 adjacent to the bottom surface 114. The chip card 40 can be slidably inserted into the chamber 11 along the guiding grooves 1121, 1131. The bottom surface 114 defines a slot 1143 and a through hole 1141 set at the bottom of the slot 1143, and the through hole 1141 and the slot 1143 have about rectangle shapes. The length and the width of the slot 1143 are larger than the length and the width of the through hole 1141.

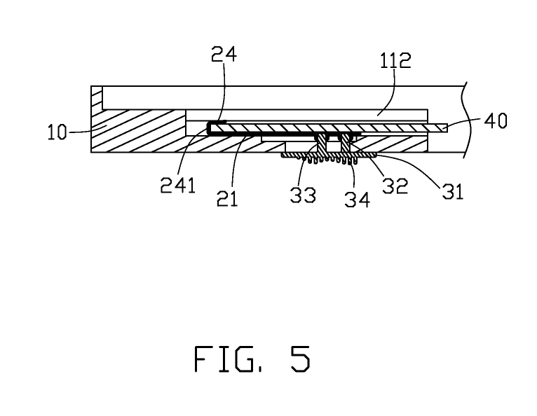

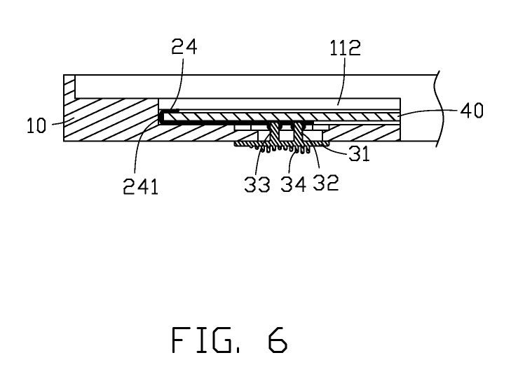

Referring to FIGS. 5-6, the retaining member 20 is made of elastic material and includes a main body 21, two mounting holes 22, 23 defined at one end of the main body 21 and a bent portion 24 positioned at another end of the main body 21. The main body 21 has sheet-shape and is configured for supporting the chip card 40. The main body 21 defines two receiving sections 221, 231 facing toward the bottom surface 114, and the receiving sections 221, 231 have hollow shapes around the mounting holes 22, 23. The height of the receiving sections 221, 231 are about equal to the depth of the slot 1143, so that the receiving sections 221, 231 can slide in the slot 1143. The length of the chip card 40 is larger than the length of the main body 21. The bent portion 24 is substantially an L-shape plate extending along a peripheral edge of the main body 21. The bent portion 24 includes a connection section 241 perpendicularly extending from the edge of the main body 21 and a resisting section 242 perpendicularly extending from an edge of the connection section 241. The resisting section 242 is parallel with the main body 21. A receiving space 243 configured for securing one end of the chip card 40 is formed by the bent portion 24 and the main body 21.

The sliding button 30 includes a pressing portion 31, two connecting portions 32, 33 perpendicularly protruding from one side of the pressing portion 31 and a pushing portion 34 upwardly extending from another side of the pressing portion 31. The connecting portions 32, 33 can be respectively accommodated within the mounting holes 22, 23 through the through hole 1141 and the receiving sections 221, 231, so that the retaining member 20 can be fixed with the sliding button 30. The distance of the two receiving sections 221 and 231 is less than the length of the through hole 1141, so that the receiving sections 221 and 231 can slide in the through hole 1141. The surface of the pushing portion 34 is generally wave-shaped to be convenient for pushing the sliding button 30.

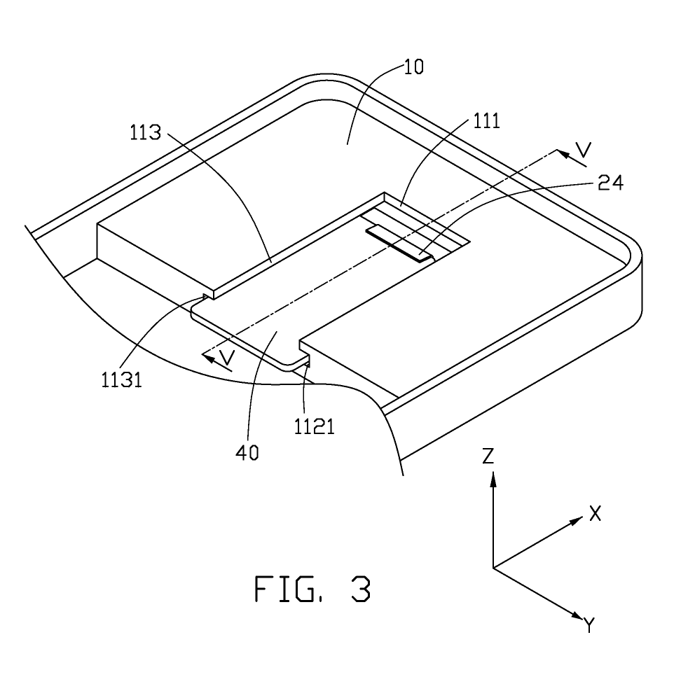

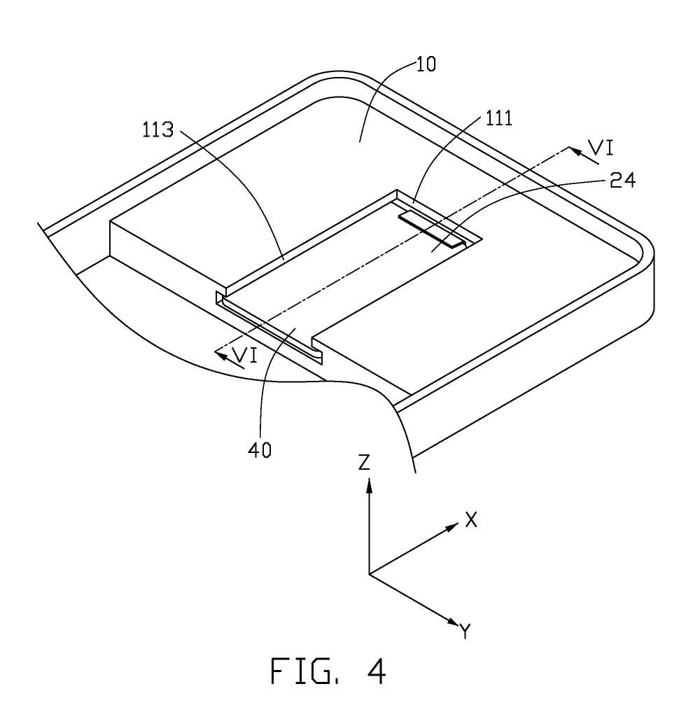

Also referring to FIGS. 3-4, in assembly, the retaining member 20 is placed on the bottom surface 114 and the bent portion 24 is adjacent to the stopping wall 111. Then, the connecting portions 32, 33 can be respectively accommodated within the mounting holes 22, 23 through the through hole 1141 and the receiving sections 221, 231, so that the retaining member 20 can be fixed with the sliding button 30. Next, the chip card 40 is inserted into the guiding grooves 1121 and 1131 until one end of the chip card 40 is received in and abuts interior of the receiving space 243. The chip card 40 is pushed until it is fully received in the chamber 11 which causes the retaining member 20, and thus the sliding button 30 to slide to a card received position in a direction X., The chip card 40 is secured by the friction between the two sides of the chip card 40 and sidewalls of the guiding grooves 1121, 1131.

Also referring to FIG. 3, when removing the chip card 40 from the electronic device, the sliding button 30 is moved opposite to X direction from the card received position to a card eject position, which causes the retaining member 20 with the chip card 40 slide in the guiding grooves 1121, 1131 until the chip card 40 partially extends from the receiving chamber 11. After that, the connecting portion 32 is stopped by one sidewall of the through hole 1141, then the retaining member 20, the sliding button 30 and the chip card 40 stop moving. Thus, the chip card 40, being partially exposed from the chamber 11, is easy to grasp by a user and removed from the housing 10.

Understandably, the through hole 1141 and the slot 1143 may be replaced with other equally applicable shapes.

It is understood that the numbers of the connecting portions are not just limited to two, the numbers can be increased or decreased. The numbers of mounting holes of the retaining member can be matched with the numbers of the connecting portions of the sliding button.

It is to be understood, however, that even through numerous characteristics and advantages of the present disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A card holding mechanism comprising:
a housing defining a chamber therein;
a retaining member mounted in the chamber of the housing, the retaining member used for receiving a chip card; and
a sliding button slidably attached on the housing, the sliding button fixed with the retaining member to remove the chip card;
wherein when the sliding button is pushed, the retaining member with the chip card is brought out from the chamber.

2. The card holding mechanism as claimed in claim 1, wherein the retaining member includes a main body used for supporting and holding the chip card.

3. The card holding mechanism as claimed in claim 2, wherein the retaining member further includes a bent portion positioned at one end of the main body, a receiving space configured for securing one end of the chip card is formed by the bent portion and the main body.

4. The card holding mechanism as claimed in claim 3, wherein the bent portion includes a connection section extending from the edge of the main body and a resisting section extending from an edge of the connection section, and the resisting section is parallel with the main body.

5. The card holding mechanism as claimed in claim 4, wherein the retaining member is made of elastic material, when one end of the chip card is secured by the receiving space, the chip card is resisted between the resisting section and the main body.

6. The card holding mechanism as claimed in claim 3, wherein the main body defines at least one receiving section thereon, and the sliding button includes at least one connecting portion thereon, the connecting portion is fixed in the receiving section to connect the retaining member with the sliding button.

7. The card holding mechanism as claimed in claim 6, wherein the sliding button further includes a pushing portion used to push to remove the sliding button and retaining member.

8. The card holding mechanism as claimed in claim 6, wherein the chamber includes a stopping wall and two sidewalls extending from two ends of the stopping wall, the sidewalls define guiding grooves, the chip card can be inserted into the chamber along the guiding groves.

9. The card holding mechanism as claimed in claim 8, wherein the chamber further includes a bottom surface connected to the stopping wall and two sidewalls, the guiding grooves are adjacent to the bottom surface and is used to place the retaining member.

10. The card holding mechanism as claimed in claim 9, wherein the bottom surface defines a through hole, the connecting portion can be accommodated into the receiving section through the through hole to fix the retaining member and the sliding button.

11. A card holding mechanism, comprising:
a housing defining a chamber therein, and the bottom of the chamber defining a through hole;
a retaining member mounted in the chamber of the housing, the retaining member used for receiving a chip card; and
a sliding button slidably attached on the housing, the sliding button fixed with the retaining member through the through hole to remove the chip card;
wherein when the sliding button is pushed, the retaining member with the chip card is are brought out from the chamber.

12. The card holding mechanism as claimed in claim 11, wherein the retaining member includes a main body used for supporting and holding the chip card.

13. The card holding mechanism as claimed in claim 12, wherein the retaining member further includes a bent portion positioned at one end of the main body, a receiving space configured for securing one end of the chip card is formed by the bent portion and the main body.

14. The card holding mechanism as claimed in claim 13, wherein the bent portion includes a connection section extending from the edge of the main body and a resisting section extending from an edge of the connection section, and the resisting section is parallel with the main body.

15. The card holding mechanism as claimed in claim 14, wherein the retaining member is made of elastic material, when one end of the chip card is secured by the receiving space, the chip card is resisted between the resisting section and the main body.

16. The card holding mechanism as claimed in claim 13, wherein the main body defines at least one receiving section thereon, and the sliding button includes at least one connecting portion thereon, the connecting portion is fixed in the receiving section to connect the retaining member with the sliding button.

17. The card holding mechanism as claimed in claim 16, wherein the sliding button further includes a pushing portion used to push to remove the sliding button and retaining member.

18. The card holding mechanism as claimed in claim 16, wherein the chamber includes a stopping wall and two sidewalls extending from two ends of the stopping wall, the sidewalls define guiding grooves, the chip card can be inserted into the chamber along the guiding groves.

19. The card holding mechanism as claimed in claim 18, wherein the chamber further includes a bottom surface connected to the stopping wall and two sidewalls, the guiding grooves are adjacent to the bottom surface and is used to place the retaining member.

20. The card holding mechanism as claimed in claim 19, wherein the through hole is defined in the bottom surface, the connecting portion can be fixed in the receiving section through the through hole to fix the retaining member and the sliding button.
